(19) United States
(12) Patent Application Publication
(10) Pub. No.: US 2024/0312504 A1
(43) Pub. Date: Sep. 19, 2024

(54) ACTIVE MATERIALS FOR REDUCING HOT ELECTRON-INDUCED PUNCH-THROUGH AND RELATED APPARATUSES AND COMPUTING SYSTEMS

(71) Applicant: Micron Technology, Inc., Boise, ID (US)

(72) Inventors: Guy S. Perry, IV, Boise, ID (US); Shinichi Miyatake, Sagamihara (JP); Kyuseok Lee, Boise, ID (US)

(21) Appl. No.: 18/441,962

(22) Filed: Feb. 14, 2024

Related U.S. Application Data
(60) Provisional application No. 63/489,915, filed on Mar. 13, 2023.

(51) Int. Cl. G11C 8/08; G11C 8/14

(52) U.S. Cl. CPC G11C 8/08; G11C 8/14

(57) ABSTRACT

Active materials for reducing hot electron-induced punch-through and related apparatuses and computing systems are disclosed. An apparatus includes a first active material, a second active material, a third active material, and a fourth active material. The first active material includes a first outside edge and a first inside edge. The first outside edge defines a first notch. The second active material is spaced at substantially a minimum tolerance distance from the first active material. The third active material is spaced at substantially the minimum tolerance distance from the second active material. The fourth active material includes a second outside edge and a second inside edge. The second inside edge is spaced at substantially the minimum tolerance distance from the third active material. The second outside edge defines a second notch. A computing system includes a memory device including a subwordline driver including the apparatus.

### CROSS-REFERENCE TO RELATED APPLICATION

This application claims the benefit under 35 U.S.C. § 119(e) of U.S. Provisional Patent Application Ser. No. 63/489,915, filed Mar. 13, 2023, the disclosure of which is hereby incorporated herein in its entirety by this reference.

### TECHNICAL FIELD

This disclosure relates generally to active materials for reducing hot electron-induced punch-through (HEIP), and more specifically to geometries and spacings of active materials of transistors in subwordline drivers (SWDs).

### BACKGROUND

A subwordline driver (SWD) in a memory device is an electrical circuit that drives access lines within a memory array by providing voltage potentials for memory access operations (e.g., read, write, refresh, or erase operations, without limitation). The SWD may be used in conjunction with sense amplifiers and column decoders to perform memory access operations.

### BRIEF DESCRIPTION OF THE DRAWINGS

While this disclosure concludes with claims particularly pointing out and distinctly claiming specific embodiments, various features and advantages of embodiments within the scope of this disclosure may be more readily ascertained from the following description when read in conjunction with the accompanying drawings, in which:

FIG. 1 is a circuit schematic illustration of an SWD, according to some embodiments;

FIG. 2 is a plan view of an example of a layout design for a portion of the SWD of FIG. 1 with polysilicon hammerhead materials at ends of PMOS active materials;

FIG. 3 is a plan view of a simplified portion of the layout design of FIG. 2;

FIG. 4 is a plan view of an example of a layout design for a portion of the SWD of FIG. 1 with notches defined by active materials;

FIG. 5 is a plan view of an example of a layout design for a portion of the SWD of FIG. 1;

FIG. 6 is a plan view of an example of a layout design for a portion of the SWD of FIG. 1 with minimum tolerance distances between active materials and floating active materials at N-well boundaries;

FIG. 7 is a plan view of an example of a layout design for a portion of the SWD of FIG. 1 with notches in the active materials and minimum tolerance distances between the active materials;

FIG. 8 is a plan view of an active material, which may be used to replace one or more of the first active material, the second active material, the third active material, or the fourth active material of the layout design of FIG. 7 in some embodiments;

FIG. 9 is a plan view of an active material, which may be used to replace one or more of the first active material, the second active material, the third active material, or the fourth active material of the layout design of FIG. 7 in some embodiments;

FIG. 10 is a plan view of a pair of active materials that may be used to replace one or more of the first active material and the second active material or the third active material and the fourth active material of FIG. 7 in some embodiments; and

FIG. 11 is a block diagram of a computing system, according to some embodiments.

### DETAILED DESCRIPTION

In the following detailed description, reference is made to the accompanying drawings, which form a part hereof, and in which are shown, by way of illustration, specific examples of embodiments in which the present disclosure may be practiced. These embodiments are described in sufficient detail to enable a person of ordinary skill in the art to practice the present disclosure. However, other embodiments enabled herein may be utilized, and structural, material, and process changes may be made without departing from the scope of the disclosure.

The illustrations presented herein are not meant to be actual views of any particular method, system, device, or structure, but are merely idealized representations that are employed to describe the embodiments of the present disclosure. In some instances similar structures or components in the various drawings may retain the same or similar numbering for the convenience of the reader; however, the similarity in numbering does not necessarily mean that the structures or components are identical in size, composition, configuration, or any other property.

The following description may include examples to help enable one of ordinary skill in the art to practice the disclosed embodiments. The use of the terms “exemplary,” “by example,” and “for example,” means that the related description is explanatory, and though the scope of the disclosure is intended to encompass the examples and legal equivalents, the use of such terms is not intended to limit the scope of an embodiment or this disclosure to the specified components, steps, features, functions, or the like.

It will be readily understood that the components of the embodiments as generally described herein and illustrated in the drawings could be arranged and designed in a wide variety of different configurations. Thus, the following description of various embodiments is not intended to limit the scope of the present disclosure, but is merely representative of various embodiments. While the various aspects of the embodiments may be presented in the drawings, the drawings are not necessarily drawn to scale unless specifically indicated.

Furthermore, specific implementations shown and described are only examples and should not be construed as the only way to implement the present disclosure unless specified otherwise herein. Elements, circuits, and functions may be shown in block diagram form in order not to obscure the present disclosure in unnecessary detail. Conversely, specific implementations shown and described are exemplary only and should not be construed as the only way to implement the present disclosure unless specified otherwise herein. Additionally, block definitions and partitioning of logic between various blocks is exemplary of a specific implementation. It will be readily apparent to one of ordinary skill in the art that the present disclosure may be practiced by numerous other partitioning solutions. For the most part, details concerning timing considerations and the like have been omitted where such details are not necessary to obtain a complete understanding of the present disclosure and are within the abilities of persons of ordinary skill in the relevant art.

Those of ordinary skill in the art will understand that information and signals may be represented using any of a variety of different technologies and techniques. Some drawings may illustrate signals as a single signal for clarity of presentation and description. It will be understood by a person of ordinary skill in the art that the signal may represent a bus of signals, wherein the bus may have a variety of bit widths and the present disclosure may be implemented on any number of data signals including a single data signal.

The embodiments may be described in terms of a process that is depicted as a flowchart, a flow diagram, a structure diagram, or a block diagram. Although a flowchart may describe operational acts as a sequential process, many of these acts can be performed in another sequence, in parallel, or substantially concurrently. In addition, the order of the acts may be re-arranged.

Any reference to an element herein using a designation such as “first,” “second,” and so forth does not limit the quantity or order of those elements, unless such limitation is explicitly stated. Rather, these designations may be used herein as a convenient method of distinguishing between two or more elements or instances of an element. Thus, a reference to first and second elements does not mean that only two elements may be employed there or that the first element must precede the second element in some manner. In addition, unless stated otherwise, a set of elements may include one or more elements.

As used herein, the term “substantially” in reference to a given parameter, property, or condition means and includes to a degree that one of ordinary skill in the art would understand that the given parameter, property, or condition is met with a small degree of variance, such as, for example, within acceptable manufacturing tolerances. By way of example, depending on the particular parameter, property, or condition that is substantially met, the parameter, property, or condition may be at least 90% met, at least 95% met, or even at least 99% met.

As used herein, “conductive material” means and includes electrically conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fc), ruthenium (Ru), osmium (Os), cobalt (Co), rhodium (Rh), iridium (Ir), nickel (Ni), palladium (Pd), platinum (Pt), copper (Cu), silver (Ag), gold (Au), aluminum (Al)), an alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively-doped semiconductor material (e.g., conductively-doped polysilicon, conductively-doped germanium (Ge), conductively-doped silicon germanium (SiGe)). In addition, a “conductive structure” means and includes a structure formed of and including conductive material.

As used herein, “insulative material” means and includes electrically insulative material, such as one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbO—ₓ—), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), at least one dielectric oxycarbide material (e.g., silicon oxycarbide (SiOₓC_{y})), at least one hydrogenated dielectric oxycarbide material (e.g., hydrogenated silicon oxycarbide (SiCₓO_{y}H_{z})), and at least one dielectric carboxynitride material (e.g., a silicon carboxynitride (SiOₓC_{z}N_{y})). Formulae including one or more of “x,” “y,” and “z” herein (e.g., SiOₓ, AlOₓ, HfOₓ, NbO—ₓ, TiOₓ, SiN_{y}, SiOₓ N_{y}, SiOₓC_{y}, SiCₓO_{y}H_{z}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions. In addition, an “insulative structure” means and includes a structure formed of and including insulative material.

As used herein, the term “semiconductor material” refers to a material having an electrical conductivity between those of insulative materials and conductive materials. For example, a semiconductor material may have an electrical conductivity of between about 10⁻⁸ Siemens per centimeter (S/cm) and about 10⁴ S/cm (10⁶ S/m) at room temperature. Examples of semiconductor materials include elements found in column IV of the periodic table of elements such as silicon (Si), germanium (Ge), and carbon (C). Other examples of semiconductor materials include compound semiconductor materials such as binary compound semiconductor materials (e.g., gallium arsenide (GaAs)), ternary compound semiconductor materials (e.g., Al_{X}Ga_{1-X}As), and quaternary compound semiconductor materials (e.g., Ga_{X}In_{1-X}As_{Y}P_{1-Y}), without limitation. Compound semiconductor materials may include combinations of elements from columns III and V of the periodic table of elements (III-V semiconductor materials) or from columns II and VI of the periodic table of elements (II-VI semiconductor materials), without limitation. Semiconductor devices often include crystalline semiconductor materials. By way of non-limiting examples, transistors and diodes include crystalline semiconductor materials.

As used herein, the term “intrinsic semiconductor material” refers to a semiconductor material having a relatively small density of impurities (e.g., a lower density of impurities than electron and hole densities resulting from thermal generation at room temperature).

As used herein, the term “doped semiconductor material” refers to a semiconductor material having a higher density of impurities introduced thereto than intrinsic semiconductor materials (e.g., a higher density of impurities than electron and hole densities resulting from thermal generation at room temperature). A doped semiconductor material may be doped predominantly with donor impurities such as phosphorus (P), antimony (Sb), bismuth (Bi), and arsenic (As), without limitation. Each donor impurity in a crystal lattice of semiconductor material adds a free electron, which increases the conductivity of the semiconductor material relative to the intrinsic form of the semiconductor material. Doped semiconductor materials that have been doped predominantly with donor impurities are referred to herein as “N-type semiconductor materials.” A doped semiconductor may instead be doped predominantly with trivalent or acceptor impurities such as boron (B), indium (In), aluminum (Al), and gallium (Ga), without limitation. Each trivalent or acceptor impurity in a crystal lattice of semiconductor material adds an electron hole (referred to herein as “hole”), which increases the conductivity of the semiconductor material relative to the intrinsic form of the semiconductor material. Doped semiconductor materials that have been doped predominantly with trivalent or acceptor impurities are referred to herein as “P-type semiconductor materials.”

As used herein, the term “active material” refers to a semiconductor material that has been doped to function as a channel material in a metal oxide semiconductor (MOS) field effect transistor (FET) (MOSFET). A MOSFET transistor having a channel material that has been doped predominantly with donor impurities is referred to herein as a P-type MOS (PMOS) transistor because the active material serving as the channel material for the PMOS transistor includes N-type semiconductor material that inverts to form a P-type channel. Similarly, a MOSFET transistor having a channel material that has been doped predominantly with trivalent or acceptor impurities is referred to herein as an N-type MOS (NMOS) transistor because the active material serving as the channel material for the PMOS transistor includes N-type semiconductor material that inverts to form an N-type channel.

Hot Electron-Induced Punch-through (HEIP) may occur in SWDs of memory devices responsive to relatively high electrical current flowing through a subwordline. This relatively high electrical current may provide sufficient energy to electrons to “punch through” an oxide material of transistors (e.g., MOSFETs) of the SWD, which may create a current leakage path that can cause errors in operation. These errors may effect reliability of memory devices and reduce the overall performance of the memory devices.

To reduce HEIP, various techniques may be used. For example, a reduced subwordline current may be used, which reduces the probability that electrons obtain sufficient energy to punch through an oxide material barrier (e.g., a shallow trench isolation barrier, gate oxide barriers, without limitation). As another example, a thickness of these oxide material barriers may be increased. As a further example, materials having relatively high breakdown voltage potentials may be used for these oxide material barriers.

In addition to or instead of these HEIP reducing techniques, various embodiments disclosed herein relate to reduction of HEIP using geometries and spacings of active materials of transistors. Although the embodiments disclosed herein are discussed in the context of SWDs of memory devices, the geometries and spacings of active materials disclosed herein may be used in other portions of memory devices or in devices other than memory devices to reduce HEIP in these other portions of memory devices or in the other devices.

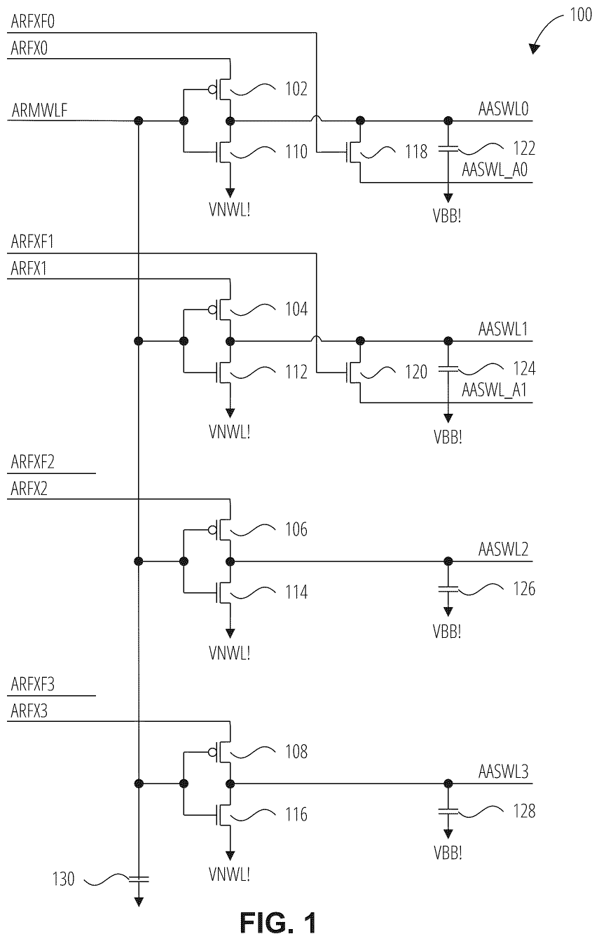

FIG. 1 is a circuit schematic illustration of an SWD 100, according to some embodiments. The SWD 100 is configured to receive a common main word line (MWL) signal (via ARFXF0, ARFX0, ARFXF1, ARFX1, ARFXF2, ARFX2, ARFXF3, ARFX3). The MWL indicates one of subwordlines AASWL0, AASWL_A0, AASWL1, AASWL_A1, AASWL2, or AASWL3. The SWD 100 is configured to select the indicated one of the subwordlines AASWL0, AASWL_A0, AASWL1, AASWL_A1, AASWL2, or AASWL3 to access the indicated one of the subwordlines.

The SWD 100 includes a first transistor 102, a second transistor 104, a third transistor 106, and a fourth transistor 108, which are PMOS transistors. The SWD 100 also includes several NMOS transistors 110, 112, 114, 116, 118, and 120 and capacitors 122, 124, 126, 128, and 130. The first transistor 102 is electrically connected in series with the NMOS transistor 110 with a drain terminal of the NMOS transistor 110 electrically connected to a drain terminal of the first transistor 102. Drain terminals of the first transistor 102, the NMOS transistor 110, and the NMOS transistor 118 are electrically connected to subwordline AASWL0. A source terminal of the NMOS transistor 110 is electrically connected to a predetermined voltage potential node VNWL!. A source terminal of the first transistor 102 is electrically connected to MWL node ARFX0. A source terminal of the NMOS transistor 118 is electrically connected to subwordline ASWL_A0. A gate terminal of the NMOS transistor 118 is electrically connected to MWL node ARFX0. Capacitor 122 is electrically connected from subwordline AASWL0 to a voltage potential node VBB!.

The second transistor 104 is electrically connected in series with the NMOS transistor 112 with a drain terminal of the NMOS transistor 112 electrically connected to a drain terminal of the second transistor 104. Drain terminals of the second transistor 104, the NMOS transistor 112, and the NMOS transistor 120 are electrically connected to subwordline AASWL1. A source terminal of the NMOS transistor 112 is electrically connected to the predetermined voltage potential node VNWL!. A source terminal of the second transistor 104 is electrically connected to MWL node ARFX1. A source terminal of the NMOS transistor 120 is electrically connected to subwordline ASWL_A1. A gate terminal of the NMOS transistor 120 is electrically connected to MWL node ARFXF1. Capacitor 124 is electrically connected from subwordline AASWL1 to the voltage potential node VBB!.

The third transistor 106 is electrically connected in series with the NMOS transistor 114 with a drain terminal of the NMOS transistor 114 electrically connected to a drain terminal of the third transistor 106. Drain terminals of the third transistor 106 and the NMOS transistor 114 are electrically connected to subwordline AASWL2. A source terminal of the NMOS transistor 114 is electrically connected to the predetermined voltage potential node VNWL!. A source terminal of the third transistor 106 is electrically connected to MWL node ARFX2. Capacitor 126 is electrically connected from subwordline AASWL2 to the voltage potential node VBB!.

The fourth transistor 108 is electrically connected in series with the NMOS transistor 116 with a drain terminal of the NMOS transistor 116 electrically connected to a drain terminal of the fourth transistor 108. Drain terminals of the fourth transistor 108 and the NMOS transistor 116 are electrically connected to subwordline AASWL3. A source terminal of the NMOS transistor 116 is electrically connected to the predetermined voltage potential node VNWL!. A source terminal of the fourth transistor 108 is electrically connected to MWL node ARFX3. Capacitor 128 is electrically connected from subwordline AASWL3 to the voltage potential node VBB!.

Gate terminals of the first transistor 102, the second transistor 104, the third transistor 106, the fourth transistor 108, and the NMOS transistors 110, 112, 114, and 116 are electrically connected to an ARMWLF terminal. Accordingly, the gate terminals of the first transistor 102, the second transistor 104, the third transistor 106, the fourth transistor 108, and the NMOS transistors 110, 112, 114, and 116 are electrically connected together.

Some voltage potential differentials applied to the SWD 100 may be sufficiently large to merit the use of protection across active materials of the PMOS transistors (first transistor 102, second transistor 104, third transistor 106, and fourth transistor 108) to reduce HEIP. Various embodiments corresponding to various different geometries and spacings for the active materials of these PMOS transistors first transistor 102, second transistor 104, third transistor 106, and fourth transistor 108 are disclosed herein. Some of the embodiments disclosed herein correspond to larger costs in terms of chip area, or “real estate,” than others. In some of these embodiments, specific protections may be applied to each individual active material of the first transistor 102, the second transistor 104, the third transistor 106, and the fourth transistor 108. A large number of repetitions of the SWD 100 of FIG. 1 in a memory chip may, therefore, result in a relatively large cost in terms of chip area. By using a combination of layout techniques disclosed herein, reduction in the chip area penalties may be reduced without adding significant risk of HEIP. Accordingly, array efficiency per die may be increased, reticle field efficiency may be increased, and a number of dies per wafer may be increased, which may reduce the overall cost per die.

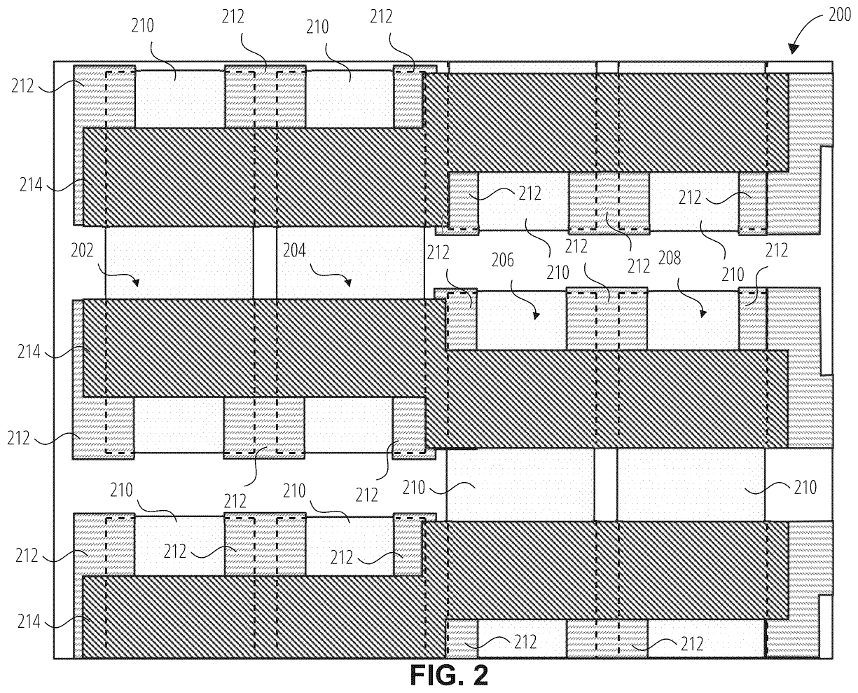

FIG. 2 is a plan view of an example of a layout design 200 for a portion of the SWD 100 of FIG. 1 with polysilicon hammerhead materials 212 at ends of PMOS active materials 210. The layout design 200 illustrates several transistors including a first transistor 202, a second transistor 204, a third transistor 206, and a fourth transistor 208 at intersections between the active materials 210 and gate materials 214. The active materials 210 may include N-type semiconductor material and the transistors may be PMOS transistors. Edges of the active materials 210 that are behind the active materials 210 and the polysilicon hammerhead materials 212 are illustrated using broken lines. The first transistor 202, the second transistor 204, the third transistor 206, and the fourth transistor 208 are examples of the first transistor 102, the second transistor 104, the third transistor 106, and the fourth transistor 108 of FIG. 1. Other portions of the SWD 100 such as the NMOS transistors 110, 112, 114, 116, 118, and 120 and the capacitors 122, 124, 126, 128, and 130 are not shown.

The polysilicon hammerhead materials 212 are disposed over shallow trench isolation (STI) edges of the first transistor 202, the second transistor 204, the third transistor 206, and the fourth transistor 208. The polysilicon hammerhead materials 212 may increase an effective length of the transistors (e.g., the first transistor 202, the second transistor 204, the third transistor 206, and the fourth transistor 208) to protect against HEIP. The inclusion of the polysilicon hammerhead materials 212, however, causes each active material 210 to be 70 nanometers (nm) wider than the effective device width. Since there are four PMOS transistors in each SWD (e.g., the SWD 100 of FIG. 1), a total of 280 nm is added to the width of each SWD. In a non-limiting example in which ten SWDs are included in each array bank, and sixteen array banks are included across the die, a total of 44.8 microns (μm) may be added as a result of the polysilicon hammerhead materials 212.

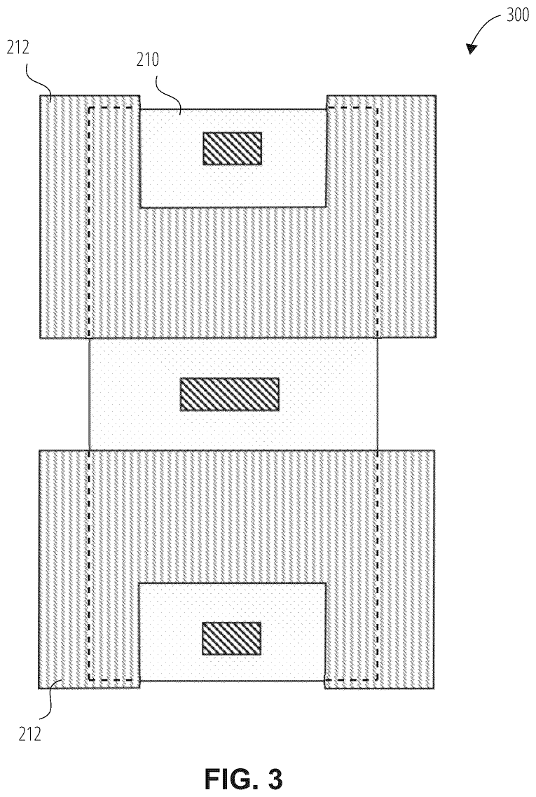

FIG. 3 is a plan view of a simplified portion 300 of the layout design 200 of FIG. 2. The gate materials 214 are not illustrated in FIG. 3 to enable more complete visualization of the polysilicon hammerhead materials 212. As illustrated in FIG. 3, the polysilicon hammerhead materials 212 are positioned over and beyond the edges of the ends of the active materials 210, which extends the footprint of each of the PMOS transistors (the first transistor 202, the second transistor 204, the third transistor 206, and the fourth transistor 208). Accordingly, in the example illustrated in FIG. 2, HEIP protection may come at the cost of chip area to accommodate the polysilicon hammerhead materials 212.

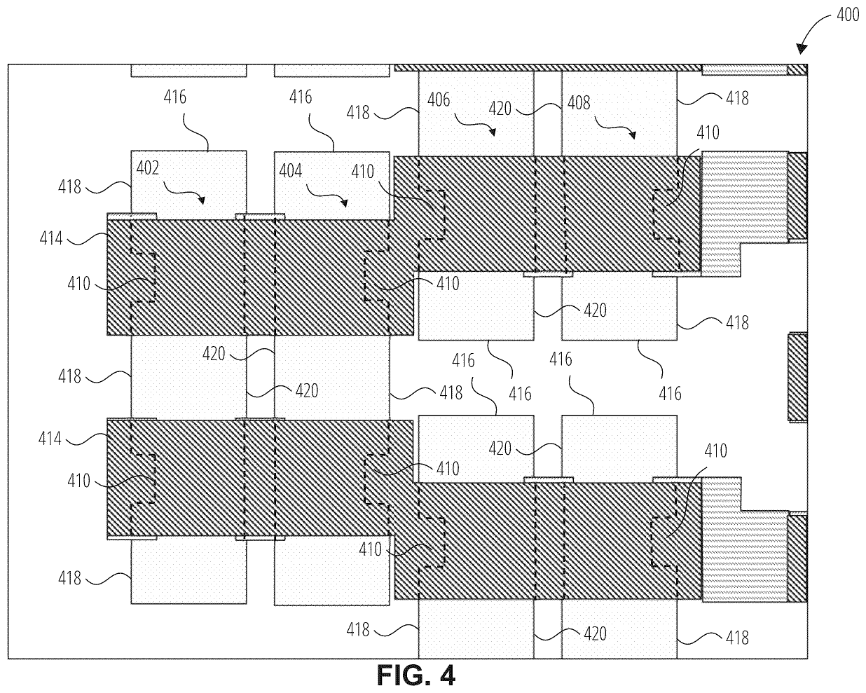

FIG. 4 is a plan view of an example of a layout design 400 for a portion of the SWD 100 of FIG. 1 with notches 410 defined by active materials 416. The layout design 400 includes several transistors at overlaps between active materials 416 and gate materials 414. For example, the layout design 400 includes a first transistor 402, a second transistor 404, a third transistor 406, and a fourth transistor 408, which are examples of the first transistor 102, the second transistor 104, the third transistor 106, and the fourth transistor 108 of FIG. 1. The active materials 416 are arranged in pairs that are vertically staggered, from the perspective illustrated in FIG. 4, with other pairs of the active materials 416. The active materials 416 include outside edges 418 facing outwardly from these staggered pairs and inside edges 420 opposite the outside edge 418 facing inwardly to these staggered pairs.

The outside edges 418 define notches 410 reducing a width of the active materials 416 relative to that of other portions of the active materials 416. The notches 410 are positioned at portions of the outside edges 418 that are overlapped by the gate materials 414. The notch 410 may increase effective lengths of the transistors (e.g., effective lengths of the first transistor 402, the second transistor 404, the third transistor 406, and the fourth transistor 408) compared to equivalently sized transistors that do not include notches in their active materials. This increased effective lengths of the first transistor 402, the second transistor 404, the third transistor 406, and the fourth transistor 408 may reduce HEIP. This reduction in HEIP may be accomplished without the use of polysilicon hammerhead materials (e.g., such as the polysilicon hammerhead materials 212 illustrated in FIG. 2 and FIG. 3) at the ends of the active materials 416, which increases the overall footprint of the SWD, as discussed above with reference to FIG. 2 and FIG. 3. Accordingly, the layout design 400 of FIG. 4 for the SWD 100 of FIG. 1 may result in area savings as compared to the layout design 200 of FIG. 2.

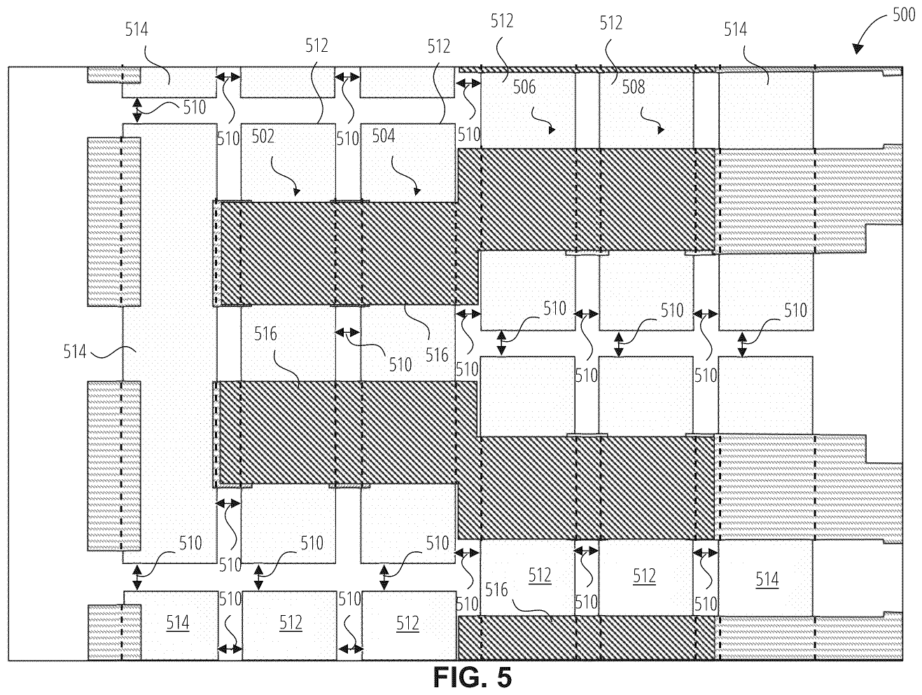

FIG. 5 is a plan view of an example of a layout design 500 for a portion of the SWD 100 of FIG. 1 with minimum tolerance distances 510 between active materials 512. The layout design 500 includes transistors at overlaps between gate materials 516 and the active materials 512. For example, the layout design 500 includes a first transistor 502, a second transistor 504, a third transistor 506, and a fourth transistor 508, which are examples of the first transistor 102, the second transistor 104, the third transistor 106, and the fourth transistor 108 of FIG. 1.

Reducing spaces between the active materials 512 may reduce HEIP leakage without using polysilicon hammerhead materials such as the polysilicon hammerhead materials 212 of FIG. 2 and FIG. 3. Unfortunately, however, floating active materials 514 may be included in the layout design 500. The floating active material 514 are electrically floating, or in other words, not electrically connected to a power supply or reference voltage potential node. These floating active materials 514 may add an area cost to the layout design 500, which may even negate some of the area savings for not using polysilicon hammerhead materials.

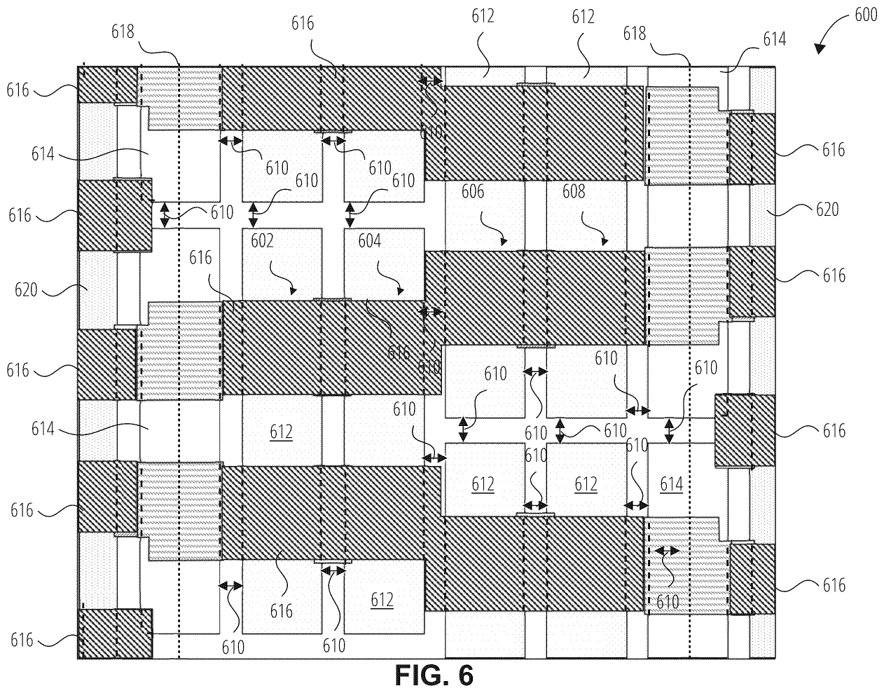

FIG. 6 is a plan view of an example of a layout design 600 for a portion of the SWD 100 of FIG. 1 with minimum tolerance distances between active materials 612 and floating active materials 614 at N-well boundaries 618. The layout design 600 illustrates several transistors (PMOS transistors) at intersections between active materials 612 and gate materials 616 including a first transistor 602, a second transistor 604, a third transistor 606, and a fourth transistor 608. The first transistor 602, the second transistor 604, the third transistor 606, and the fourth transistor 608 are examples of the first transistor 102, the second transistor 104, the third transistor 106, and the fourth transistor 108 of FIG. 1. The layout design 600 also illustrates several NMOS transistors (e.g., one or more of the NMOS transistors 110, 112, 114, 116, 118, or 120 of FIG. 1) at intersections between P-type active materials 620 and the gate materials 616. N-well boundaries 618 are illustrated between portions of the layout design 600 that include P-type transistors and portions of the layout design 600 that include N-type transistors.

The layout design 600 is similar to the layout design 500 of FIG. 5 except that the floating active materials 614 are disposed at the N-well boundaries 618. Chip area near the N-well boundary 618 may not typically be utilized for other materials. As a result, at least a portion of an area penalty corresponding to the floating active materials 614 may be absorbed by chip area that is typically not occupied, and the total chip area penalty of the layout design 600 due to the floating active materials 614 may be reduced as compared to that of the layout design 500 of FIG. 5. By way of non-limiting example, a per SWD reduction in width of the layout design 600 as compared to that of the layout design 500 may be substantially 280 nm.

Although, like the layout design 500 of FIG. 5, the layout design 600 may provide sufficient protection against HEIP though without the area penalty associated with the active materials 512 of FIG. 5, a substantially four times increase in leakage current may result in the layout design 600 as compared to the layout design 500 of FIG. 5 due to a Zener diode that is formed with the floating active materials 614 at the well N-well boundaries 618. More specifically, a P-N junction may be formed between the floating active material 614 and the N-well. Accordingly, although the layout design 600 is associated with a smaller area penalty than that of the layout design 500 of FIG. 5, the layout design 600 is also associated with a larger leakage current penalty than that of the layout design 500 of FIG. 5.

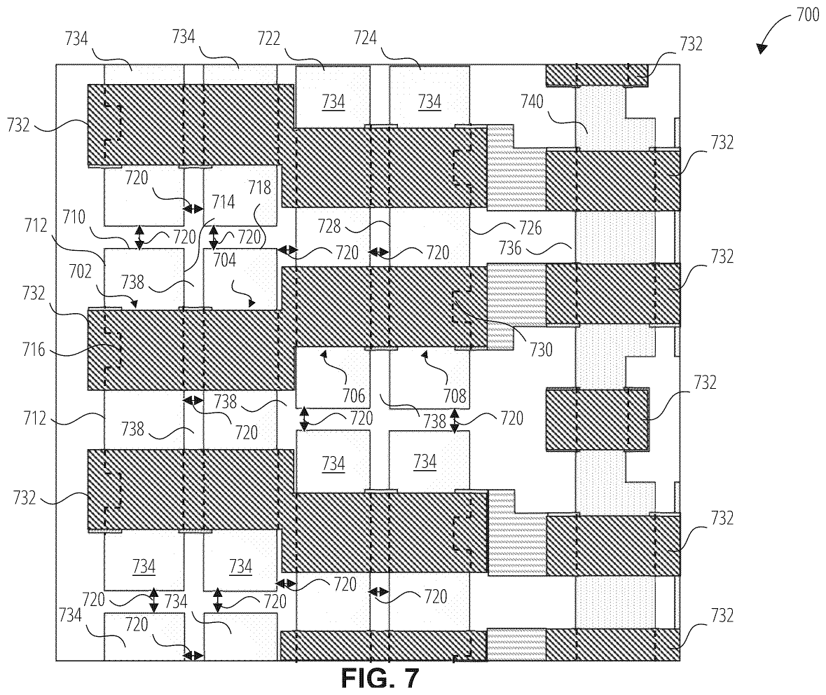

FIG. 7 is a plan view of an example of a layout design 700 for a portion of the SWD 100 of FIG. 1 with notches in the active materials 734 and minimum tolerance distances 720 between the active materials 734. The layout design 600 is a hybrid of the notch implementation discussed above with respect to FIG. 4 with the minimum tolerance distance spacing implementation discussed above with reference to FIG. 5 and FIG. 6. Accordingly, the layout design 700 takes advantage of the reduced HEIP resulting from spacing the active materials 734 from each other at the minimum tolerance distance 720 as well as the reduced HEIP resulting from inclusion of notches in the active materials 734.

The layout design 700 includes active materials 734 (N-type active materials for PMOS transistors) including a first active material 710, a second active material 718, a third active material 722, and a fourth active material 724. The layout design 700 also includes gate material 732 overlapping with active materials 734 including the first active material 710, the second active material 718, the third active material 722, and the fourth active material 724. The layout design 700 includes a first transistor 702 at the overlap of the gate material 732 and the first active material 710. The layout design 700 includes a second transistor 704 at the overlap of the gate material 732 and the second active material 718. The layout design 700 includes a third transistor 706 at the overlap of the gate material 732 and the third active material 722. The layout design 700 includes a fourth transistor 708 at the overlap of the gate material 732 and the fourth active material 724. The first transistor 702, the second transistor 704, the third transistor 706, and the fourth transistor 708 are examples of the first transistor 102, the second transistor 104, the third transistor 106, and the fourth transistor 108 of FIG. 1. The layout design 700 also includes NMOS transistors at overlaps of the gate material 732 with a P-type active material 740, which are examples of one or more of the NMOS transistors 110, 112, 114, 116, 118, or 120 of FIG. 1. The second outside edge 726 faces the P-type active material 740, which is an active material of an opposite type to that of the fourth active material 724, which is an N-type active material. In some embodiments the first outside edge 712 may face a memory cell array (e.g., a memory cell array may, in some embodiments, be disposed to the left of the layout design 700 of FIG. 7 from the perspective of FIG. 7).

The first active material 710 includes a first outside edge 712 and a first inside edge 714 opposite the first outside edge 712. The first outside edge 712 defines a first notch 716 reducing a width of the first active material 710 relative to that of other portions of the first active material 710. The second active material 718 is spaced at substantially a minimum tolerance distance 720 from the first inside edge 714 of the first active material 710. The third active material 722 is spaced at substantially the minimum tolerance distance 720 from the second active material 718. The second active material 718 is between the first active material 710 and the third active material 722. The fourth active material 724 includes a second outside edge 726 and a second inside edge 728 opposite the second outside edge 726. The second inside edge 728 is spaced at substantially the minimum tolerance distance 720 from the third active material 722. The third active material 722 is between the second active material 718 and the fourth active material 724. The second outside edge 726 defines a second notch 730 reducing a width of the fourth active material 724 relative to that of other portions of the fourth active material 724. The middle two active materials 734 of each SWD (e.g., the second active material 718 and the third active material 722) may utilize the minimum tolerance distance approach while the outer two active materials 734 may utilize the notch approach to protect themselves while protecting the inner two.

The gate material 732 overlaps a portion of the first outside edge 712 that defines the first notch 716 and a portion of the second outside edge 726 that defines the second notch 730. Accordingly, effective lengths of the first transistor 702 and the fourth transistor 708 are larger than that of the second transistor 704 and the third transistor 706.

In some embodiments, the layout design 700 includes shallow trench isolation (STI) materials 738 between the active materials 734. For example, the layout design 700 may include STI materials 738 between the first active material 710 and the second active material 718, between the second active material 718 and the third active material 722, and between the third active material 722 and the fourth active material 724.

In contrast to the layout design 500 of FIG. 5 and the layout design 600 of FIG. 6, a lateral area defined by the second outside edge 726 and an edge 736 of the P-type active material 740 is free of a floating active material such as the floating active material 514 of FIG. 5 or the floating active material 614 of FIG. 6. Accordingly, SWDs implemented according to the layout design 700 of FIG. 7 may occupy smaller chip areas than those implemented according to the layout design 500 of FIG. 5 and the layout design 600 of FIG. 6 while still operating with appropriate levels of HEIP.

Also, in contrast to the layout design 200 of FIG. 2, edges of the ends of the active materials 734 are free of polysilicon hammerhead materials such as the polysilicon hammerhead materials 212 of FIG. 2 and FIG. 3. Accordingly, the layout design 700 may achieve acceptable levels of HEIP without relying on polysilicon hammerhead materials, and therefore a SWD implemented according to the layout design 700 of FIG. 7 may occupy a smaller chip area than that of an SWD implemented according to the layout design 200 of FIG. 2.

In some embodiments an apparatus includes a first transistor including at least a portion of a first active material. The first active material includes a first outside edge and a first inside edge opposite the first outside edge. The first outside edge defines a first notch reducing a dimension of the first active material relative to that of other portions of the first active material. The apparatus includes a second transistor including at least a portion of a second active material. The second active material is spaced at substantially a minimum tolerance distance from the first inside edge of the first active material. The apparatus includes a third transistor including at least a portion of a third active material. The third active material is spaced at substantially the minimum tolerance distance from the second transistor. The apparatus includes a fourth transistor including at least a portion of a fourth active material. The fourth active material includes a second inside edge and a second outside edge opposite the second inside edge. The second inside edge is spaced the minimum tolerance distance from the third active material. The second outside edge defines a second notch reducing a dimension of the fourth active material relative to that of other portions of the fourth active material.

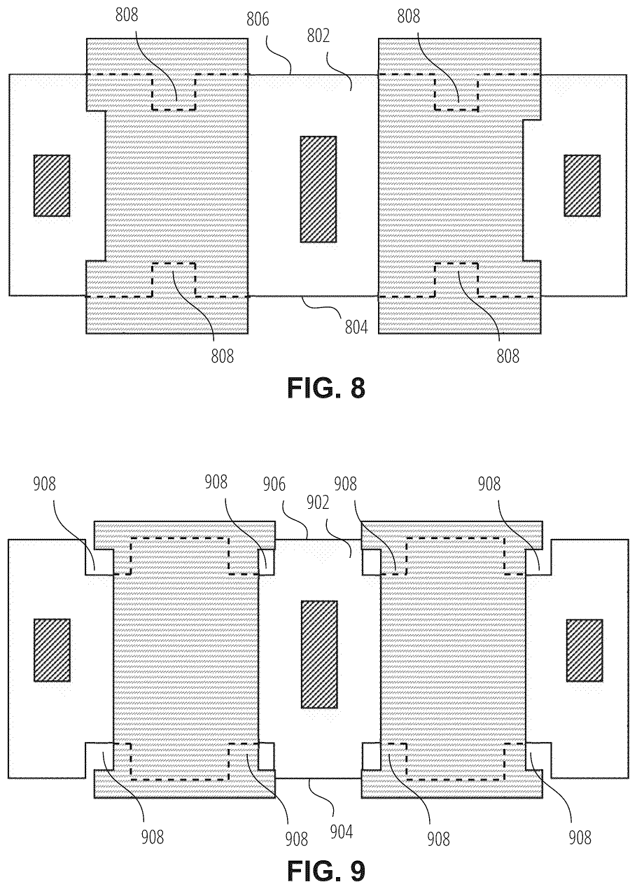

FIG. 8 is a plan view of an active material 802, which may be used to replace one or more of the first active material 710, the second active material 718, the third active material 722, or the fourth active material 724 of the layout design 700 of FIG. 7 in some embodiments. In the layout design 700 of FIG. 7, the first inside edge 714 and the second inside edge 728 are free of notches. In some embodiments, however, one or more of the first active material 710 or the fourth active material 724 may be replaced with the active material 802 of FIG. 8, which includes notches 808 defined by both an inside edge 806 and an outside edge 804 that is opposite the inside edge 806.

In addition, edges of the second active material 718 and the third active material 722 of the layout design 700 of FIG. 7 are free of notches. In some embodiments, however, one or more of the second active material 718 or the third active material 722 may be replaced with the active material 802 of FIG. 8.

FIG. 9 is a plan view of an active material 902, which may be used to replace one or more of the first active material 710, the second active material 718, the third active material 722, or the fourth active material 724 of the layout design 700 of FIG. 7 in some embodiments. The active material 902 includes an inside edge 906, an outside edge 904 opposite the inside edge 906, and notches 908 defined by the inside edge 906 and the outside edge 904. The active material 902 is similar to the active material 802 of FIG. 8 except that the active material 902 includes eight notches 908 that are sufficient for four transistors, as compared to the four notches 808 of the active material 802, which are only sufficient for four transistors.

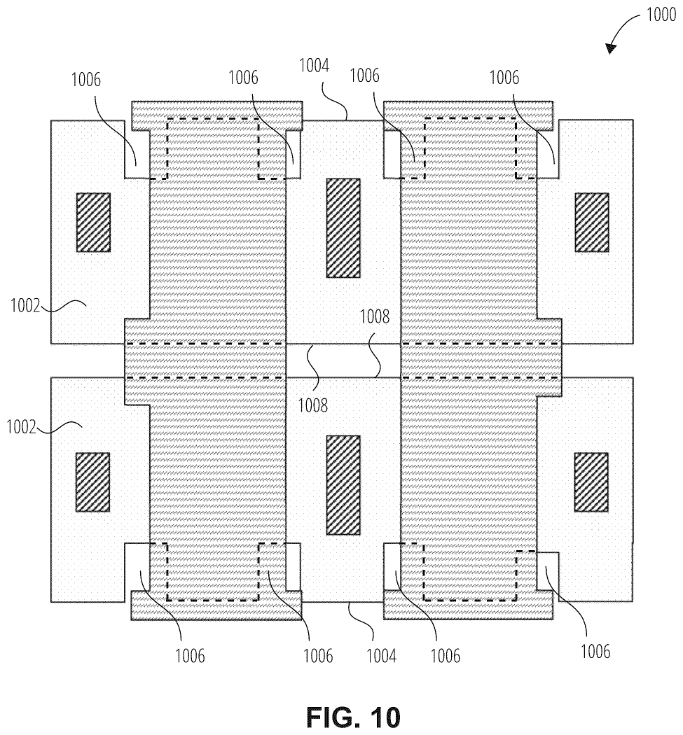

FIG. 10 is a plan view of a pair 1000 of active material 902 that may be used to replace one or more of the first active material 710 and the second active material 718 or the third active material 722 and the fourth active material 724 of FIG. 7 in some embodiments. The pair 1000 includes active materials 1002 having outside edges 1004 defining notches 1006 and having inside edges 1008 that are free of notches. The active materials 1002 are similar to the first active material 710 and the fourth active material 724 of FIG. 7 in that their outside edges 1004 define notches 1006. The active materials 1002, however, are different from the second active material 718 and the third active material 722 of FIG. 7 because the edges of the second active material 718 and the third active material 722 are free of notches.

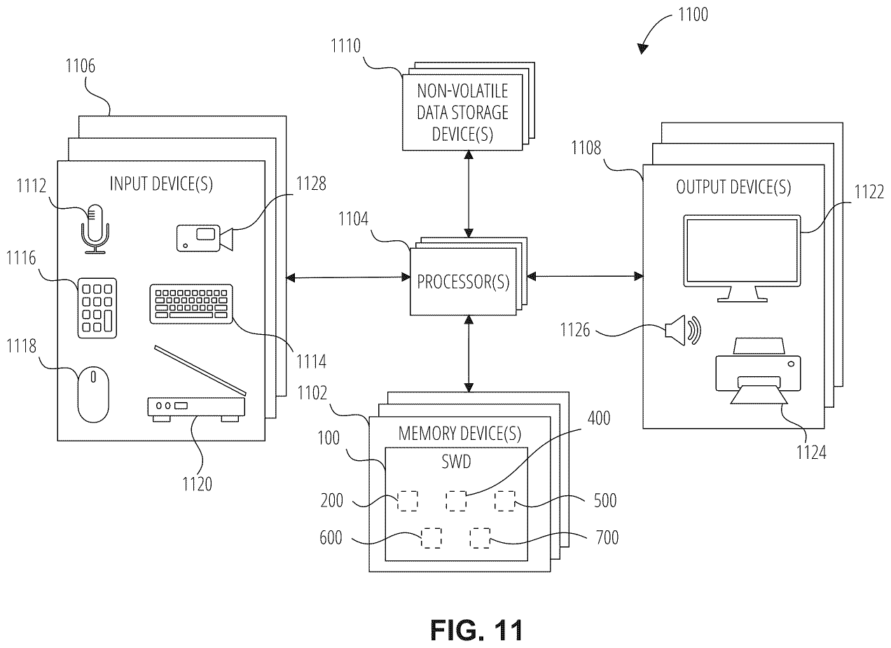

FIG. 11 is a block diagram of a computing system 1100, according to some embodiments. The computing system 1100 includes one or more processors 1104 operably coupled to one or more memory devices 1102, one or more non-volatile data storage devices 1110, one or more input devices 1106, and one or more output devices 1108. In some embodiments the computing system 1100 includes a personal computer (PC) such as a desktop computer, a laptop computer, a tablet computer, a mobile computer (e.g., a smartphone, a personal digital assistant (PDA), etc.), a network server, or other computer device.

In some embodiments the one or more processors 1104 may include a central processing unit (CPU) or other processor configured to control the computing system 1100. In some embodiments the one or more memory devices 1102 include random access memory (RAM), such as volatile data storage (e.g., dynamic RAM (DRAM), static RAM (SRAM), without limitation). In some embodiments the one or more non-volatile data storage devices 1110 include a hard drive, a solid state drive, Flash memory, erasable programmable read only memory (EPROM), other non-volatile data storage devices, or any combination thereof. In some embodiments the one or more input devices 1106 include a keyboard 1114, a pointing device 1118 (e.g., a mouse, a track pad, etc.), a microphone 1112, a keypad 1116, a scanner 1120, a camera 1128, other input devices, or any combination thereof. In some embodiments the output devices 1108 include an electronic display 1122, a speaker 1126, a printer 1124, other output devices, or any combination thereof.

In some embodiments the memory devices 1102 include a SWD 100 including a first transistor, a second transistor, a third transistor, and a fourth transistor. A first active material of the first transistor is spaced at substantially a minimum tolerance distance from a second active material of the second transistor. A third active material of the third transistor is spaced at substantially the minimum tolerance distance from the second active material. A fourth active material of the fourth transistor is spaced at substantially the minimum tolerance distance from the third active material. Outside edges of the first active material and the fourth active material define notches reducing dimensions of the first active material and the fourth active material relative to those of other portions of the first active material and the fourth active material.

In some embodiments at least a portion of the SWD 100 is implemented according to one or more of the layout design 200 of FIG. 2, the layout design 400 of FIG. 4, the layout design 500 of FIG. 5, the layout design 600 of FIG. 6, or the layout design 700 of FIG. 7.

As used in the present disclosure, the terms “module” or “component” may refer to specific hardware implementations configured to perform the actions of the module or component and/or software objects or software routines that may be stored on and/or executed by general purpose hardware (e.g., computer-readable media, processing devices, etc.) of the computing system. In some embodiments, the different components, modules, engines, and services described in the present disclosure may be implemented as objects or processes that execute on the computing system (e.g., as separate threads). While some of the system and methods described in the present disclosure are generally described as being implemented in software (stored on and/or executed by general purpose hardware), specific hardware implementations or a combination of software and specific hardware implementations are also possible and contemplated.

As used in the present disclosure, the term “combination” with reference to a plurality of elements may include a combination of all the elements or any of various different subcombinations of some of the elements. For example, the phrase “A, B, C, D, or combinations thereof” may refer to any one of A, B, C, or D; the combination of each of A, B, C, and D; and any subcombination of A, B, C, or D such as A, B, and C; A, B, and D; A, C, and D; B, C, and D; A and B; A and C; A and D; B and C; B and D; or C and D.

Terms used in the present disclosure and especially in the appended claims (e.g., bodies of the appended claims) are generally intended as “open” terms (e.g., the term “including” should be interpreted as “including, but not limited to,” the term “having” should be interpreted as “having at least,” the term “includes” should be interpreted as “includes, but is not limited to,” etc.).

Additionally, if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations.

In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.” or “one or more of A, B, and C, etc.” is used, in general such a construction is intended to include A alone, B alone, C alone, A and B together, A and C together, B and C together, or A, B, and C together, etc.

Further, any disjunctive word or phrase presenting two or more alternative terms, whether in the description, claims, or drawings, should be understood to contemplate the possibilities of including one of the terms, either of the terms, or both terms. For example, the phrase “A or B” should be understood to include the possibilities of “A” or “B” or “A and B.”

While the present disclosure has been described herein with respect to certain illustrated embodiments, those of ordinary skill in the art will recognize and appreciate that the present invention is not so limited. Rather, many additions, deletions, and modifications to the illustrated and described embodiments may be made without departing from the scope of the invention as hereinafter claimed along with their legal equivalents. In addition, features from one embodiment may be combined with features of another embodiment while still being encompassed within the scope of the invention as contemplated by the inventor.

What is claimed is:

1. An apparatus, comprising:
a first active material including a first outside edge and a first inside edge opposite the first outside edge, the first outside edge defining a first notch reducing a width of the first active material relative to that of other portions of the first active material;
a second active material spaced at substantially a minimum tolerance distance from the first inside edge of the first active material;
a third active material spaced at substantially the minimum tolerance distance from the second active material, the second active material between the first active material and the third active material; and
a fourth active material including a second outside edge and a second inside edge opposite the second outside edge, the second inside edge spaced at substantially the minimum tolerance distance from the third active material, the third active material between the second active material and the fourth active material, the second outside edge defining a second notch reducing a width of the fourth active material relative to that of other portions of the fourth active material.

2. The apparatus of claim 1, further comprising a gate material overlapping with the first active material, the second active material, the third active material, and the fourth active material.

3. The apparatus of claim 2, wherein the gate material overlaps a portion of the first outside edge that defines the first notch and a portion of the second outside edge that defines the second notch.

4. The apparatus of claim 1, wherein the second outside edge faces an active material of an opposite type to that of the fourth active material.

5. The apparatus of claim 4, wherein the active material comprises an N-type active material and the fourth active material includes a P-type active material.

6. The apparatus of claim 4, wherein a lateral area defined by the second outside edge and an edge of the active material is free of a floating active material.

7. The apparatus of claim 4, wherein a lateral area defined by the second outside edge and an edge of the active material is free of a polysilicon hammerhead material.

8. The apparatus of claim 1, wherein the first inside edge and the second inside edge are free of notches.

9. The apparatus of claim 1, wherein the first inside edge and the second inside edge define notches.

10. The apparatus of claim 1, wherein edges of the second active material and the third active material are free of notches.

11. The apparatus of claim 1, wherein edges of the second active material and the third active material define notches.

12. The apparatus of claim 1, wherein the first active material, the second active material, the third active material, and the fourth active material include an N-type active material.

13. The apparatus of claim 1, wherein the first outside edge faces a memory cell array.

14. The apparatus of claim 1, further comprising a subwordline driver (SWD) of a memory device, the SWD including a first transistor including at least a portion of the first active material, a second transistor including at least a portion of the second active material, a third transistor including at least a portion of the third active material, and a fourth transistor including at least a portion of the fourth active material.

15. The apparatus of claim 1, further comprising shallow trench isolation (STI) materials between the first active material and the second active material, between the second active material and the third active material, and between the third active material and the fourth active material.

16. An apparatus, comprising:
a first transistor including at least a portion of a first active material, the first active material including a first outside edge and a first inside edge opposite the first outside edge, the first outside edge defining a first notch reducing a dimension of the first active material relative to that of other portions of the first active material;
a second transistor including at least a portion of a second active material, the second active material spaced at substantially a minimum tolerance distance from the first inside edge of the first active material;
a third transistor including at least a portion of a third active material, the third active material spaced at substantially the minimum tolerance distance from the second transistor; and
a fourth transistor including at least a portion of a fourth active material, the fourth active material including a second inside edge and a second outside edge opposite the second inside edge, the second inside edge spaced the minimum tolerance distance from the third active material, the second outside edge defining a second notch reducing a dimension of the fourth active material relative to that of other portions of the fourth active material.

17. The apparatus of claim 16, further comprising a subwordline driver (SWD) including the first transistor, the second transistor, the third transistor, and the fourth transistor, the SWD driven by a common main word line (MWL) signal.

18. The apparatus of claim 16, wherein gate materials of the first transistor and the fourth transistor overlap with the first notch and the second notch.

19. A computing system, comprising:
a memory device including a subwordline driver (SWD), the SWD including:
a first transistor, a second transistor, a third transistor, and a fourth transistor, a first active material of the first transistor spaced at substantially a minimum tolerance distance from a second active material of the second transistor, a third active material of the third transistor spaced at substantially the minimum tolerance distance from the second active material, a fourth active material of the fourth transistor spaced at substantially the minimum tolerance distance from the third active material, outside edges of the first active material and the fourth active material defining notches reducing dimensions of the first active material and the fourth active material relative to those of other portions of the first active material and the fourth active material.

20. The computing system of claim 19, further comprising:
one or more processors electrically connected to the memory device;
one or more input devices electrically connected to the one or more processors;
one or more non-volatile data storage devices electrically connected to the one or more processors; and
one or more output devices electrically connected to the one or more processors.
